(19) United States
(12) Patent Application Publication
(10) Pub. No.: US 2025/0185329 A1
(43) Pub. Date: Jun. 5, 2025

(54) SELECTIVE FORMATION OF ETCH STOP LAYERS AND THE STRUCTURES THEREOF

(71) Applicant: Taiwan Semiconductor Manufacturing Co., Ltd., Hsinchu (TW)

(72) Inventors: Yu-Lien Huang, Jhubei City (TW); Han Yeh, Hsinchu (TW); Yuan-Sheng Huang, Taichung City (TW); Yung-Cheng Lu, Hsinchu (TW)

(21) Appl. No.: 18/442,747

(22) Filed: Feb. 15, 2024

Related U.S. Application Data
(60) Provisional application No. 63/605,613, filed on Dec. 4, 2023.

(51) Int. Cl. H01L 29/40; H01L 21/285; H01L 29/06; H01L 29/417; H01L 29/423; H01L 29/45; H01L 29/66; H01L 29/775

(52) U.S. Cl. CPC H10D 64/01; H01L 21/28518; H10D 30/014; H10D 30/43; H10D 30/6729; H10D 30/6735; H10D 62/121; H10D 64/017; H10D 64/62

(57) ABSTRACT

A method comprises forming a gate stack over a semiconductor region, performing an epitaxy process to form a source/drain region aside of the gate stack, forming a source/drain contact plug over and electrically coupling to the source/drain region, forming a gate contact plug over and electrically coupling to the gate stack, and selectively forming an inhibitor film on a dielectric layer nearby a conductive feature. The conductive feature is selected from the group consisting of the source/drain region, the source/drain contact plug, and the gate contact plug. An etch stop layer is selectively deposited on the conductive feature, wherein the first inhibitor film prevents the first etch stop layer from being deposited thereon. The inhibitor film is then removed.

### PRIORITY CLAIM AND CROSS-REFERENCE

This application claims the benefit of the following provisionally filed U.S. Patent application: Application No. 63/605,613, filed on Dec. 4, 2023, and entitled “SEMICONDUCTOR DEVICE AND FORMATION METHOD THEREOF;” which application is hereby incorporated herein by reference.

### BACKGROUND

Transistors are basic building elements in integrated circuits. In the development of the integrated circuits, Fin Field-Effect Transistors (FinFETs) and Gate-All-Around (GAA) transistors have been used to replace planar transistors. In the formation of FinFETs, semiconductor fins are formed, and dummy gates are formed on the semiconductor fins. The formation of the dummy gates may include depositing a dummy layer such as a polysilicon layer, and then patterning the dummy layer as dummy gates. Gate spacers are formed on the sidewalls of the dummy gate stacks. Source/drain regions are formed based on semiconductor fins through epitaxy. The dummy gate stacks are then removed to form trenches between the gate spacers. Replacement gates are then formed in the trenches.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-8, 9A, 9B, 9C, 10A, 10B, 11A, 11B, 12A, 12B, 12C, 13-15, 16A, 16B, 17A, 17B, 18A, 18B, 19A-1, 19A-2, and 19B illustrate the views of intermediate stages in the formation of a Fin Field-Effect Transistor (FinFET) and contact plugs in accordance with some embodiments.

FIG. 20 illustrates a cross-sectional view of a Gate All-Around (GAA) transistor in accordance with some embodiments.

FIG. 21 illustrates a top view of some features in accordance with some embodiments.

FIG. 22 illustrates a process flow for forming a transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A transistor, the respective contact plugs, and the method of forming the same are provided. In accordance with some embodiments, conductive features such as epitaxy source/drain regions, gate contact plugs, and source/drain contact plugs are formed. Inhibitor films are selectively formed on the dielectric regions nearby the conductive features. Etch stop layers are selectively formed on the conductive features. Due to the existence of inhibitor films, the etch stop layers are formed away from the dielectric regions. Since the etch stop layers may have higher dielectric constants (k values) than the nearby dielectric regions, by reducing the sizes of the etch stop layers, the parasitic capacitance between conductive features may be reduced. The resistance of conduct plugs may also be reduced.

It is appreciated that although a Fin Field-Effect Transistor (FinFET) is discussed as an example, the embodiments may also be applied to other types of transistors such as planar transistors, Gate-All-Around (GAA) transistors, or the like. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

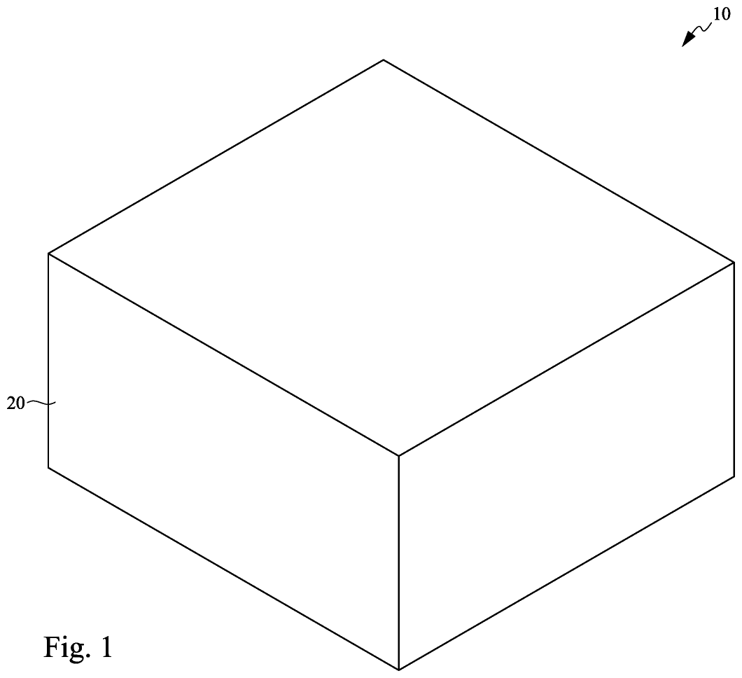

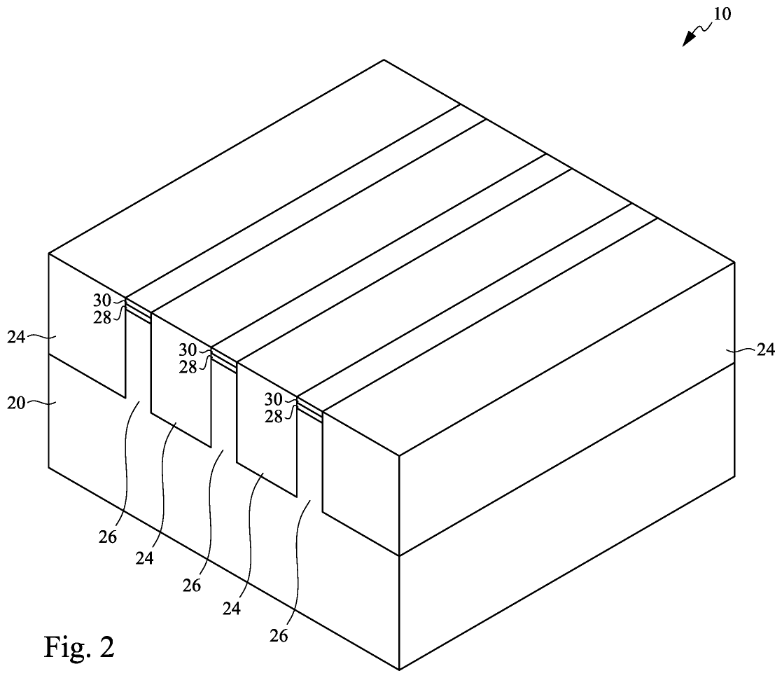

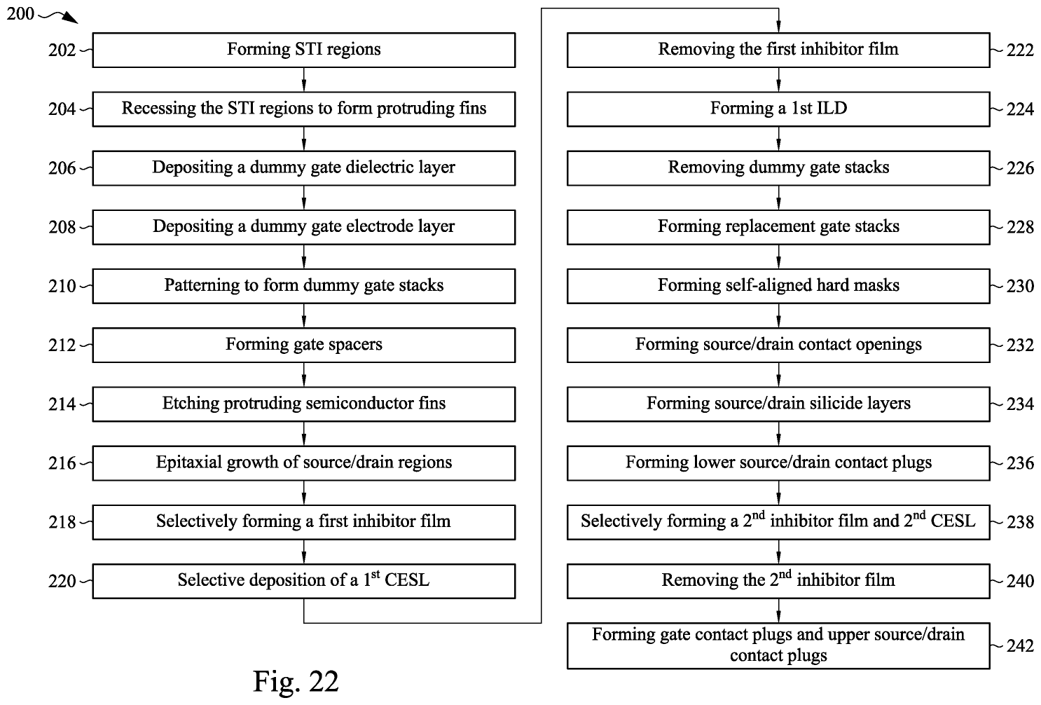

FIGS. 1-8, 9A, 9B, 9C, 10A, 10B, 11A, 11B, 12A, 12B, 12C, 13-15, 16A, 16B, 17A, 17B, 18A, 18B, 19A-1, 19A-2, and 19B illustrate the views of intermediate stages in the formation of a FinFET and contact plugs in accordance with some embodiments. The corresponding processes are also reflected schematically in the process flow 200 as shown in FIG. 22.

Referring to FIG. 1, substrate 20 is provided. The substrate 20 may be a semiconductor substrate, such as a bulk semiconductor substrate, a Semiconductor-On-Insulator (SOI) substrate, or the like, which may be doped (e.g., with a p-type or an n-type dopant) or undoped. The semiconductor substrate 20 may be a part of wafer 10, such as a silicon wafer. Generally, an SOI substrate is a layer of a semiconductor material formed on an insulator layer. The insulator layer may be, for example, a Buried Oxide (BOX) layer, a silicon oxide layer, or the like. The insulator layer is provided on a substrate, typically a silicon or glass substrate. Other substrates such as a multi-layered or gradient substrate may also be used. In some embodiments, the semiconductor material of semiconductor substrate 20 may include silicon; germanium; a compound semiconductor including carbon-doped silicon, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

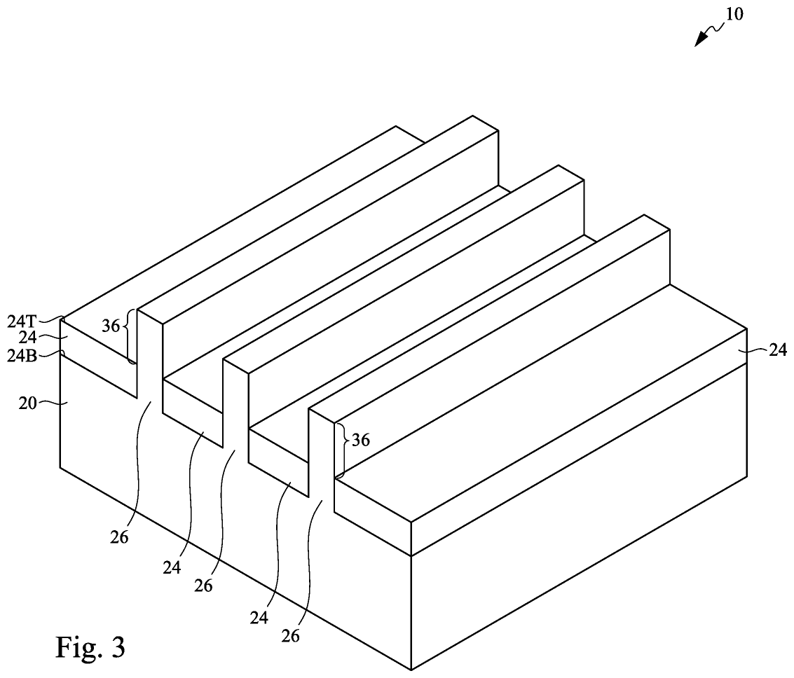

Referring to FIG. 2, isolation regions 24 are formed to extend from a top surface of substrate 20 into substrate 20. Isolation regions 24 are alternatively referred to as Shallow Trench Isolation (STI) regions hereinafter. The respective process is illustrated as process 202 in the process flow 200 as shown in FIG. 22. The portions of substrate 20 between neighboring STI regions 24 are referred to as semiconductor strips 26. To form STI regions 24, pad oxide layer 28 and hard mask layer 30 are formed on semiconductor substrate 20, and are then patterned. Pad oxide layer 28 may be a thin film formed of silicon oxide. Hard mask layer 30 may be formed of silicon nitride.

Next, the patterned hard mask layer 30 is used as an etching mask to etch pad oxide layer 28 and substrate 20, followed by filling the resulting trenches in substrate 20 with a dielectric material(s). A planarization process such as a Chemical Mechanical Polish (CMP) process or a mechanical grinding process is performed to remove excessing portions of the dielectric materials, and the remaining portions of the dielectric materials(s) are STI regions 24. STI regions 24 may include a liner dielectric (not shown), which may be a thermal oxide formed through a thermal oxidation of a surface layer of substrate 20. The liner dielectric may also be a deposited silicon oxide layer, silicon nitride layer, or the like formed using, for example, Atomic Layer Deposition (ALD), High-Density Plasma Chemical Vapor Deposition (HDPCVD), or Chemical Vapor Deposition (CVD). STI regions 24 may also include a dielectric material over the liner oxide, wherein the dielectric material may be formed using Flowable Chemical Vapor Deposition (FCVD), spin-on coating, or the like. The dielectric material over the liner dielectric may include silicon oxide in accordance with some embodiments.

Semiconductor strips 26 are between neighboring STI regions 24. In accordance with some embodiments, semiconductor strips 26 are parts of the original substrate 20, and hence the material of semiconductor strips 26 is the same as that of substrate 20. In accordance with alternative embodiments, semiconductor strips 26 are replacement strips formed by etching the portions of substrate 20 between STI regions 24 to form recesses, and performing an epitaxy to regrow another semiconductor material in the recesses. Accordingly, semiconductor strips 26 are formed of a semiconductor material different from that of substrate 20. In accordance with some embodiments, semiconductor strips 26 are formed of silicon germanium, carbon-doped silicon, or a III-V compound semiconductor material.

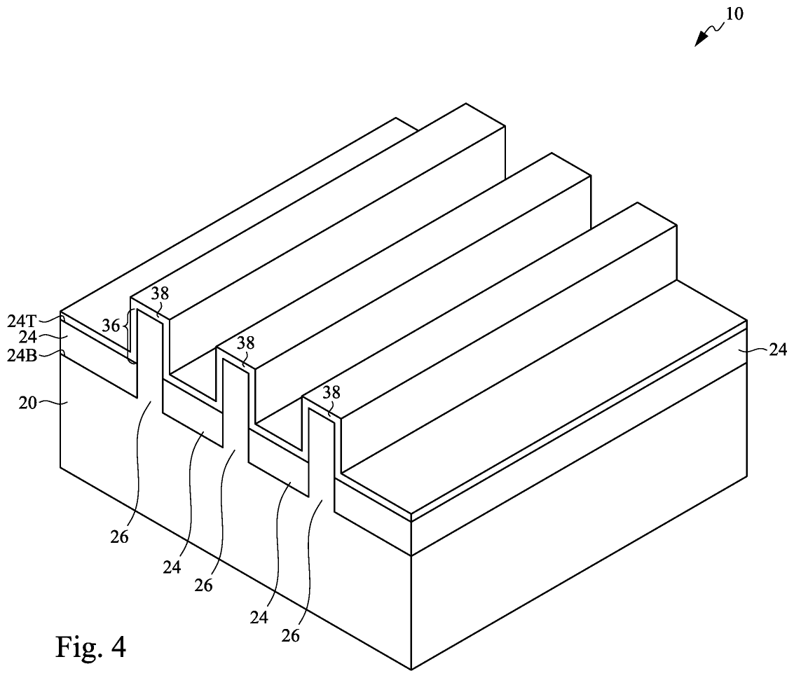

Referring to FIG. 3, STI regions 24 are recessed. The top portions of semiconductor strips 26 thus protrude higher than the top surfaces 24T of the remaining portions of STI regions 24 to form protruding fins 36. The respective process is illustrated as process 204 in the process flow 200 as shown in FIG. 22. The etching may be performed using a dry etching process, wherein HF and NH₃, for example, are used as the etching gases. During the etching process, plasma may be generated. Argon may also be included. In accordance with alternative embodiments, the recessing of STI regions 24 is performed using a wet etch process. The etching chemical may include HF, for example. The top surfaces and the bottom surfaces of STI regions 24 are referred to as 24T and 24B, respectively.

In above-illustrated embodiments, the fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins.

FIGS. 4-6 illustrate the formation of dummy gate stacks 44 in accordance with some embodiments. Referring to FIG. 4, dummy dielectric layer 38 is formed on the sidewalls and the top surfaces of protruding fins 36, and may be on the top surfaces of STI regions 24. The respective process is illustrated as process 206 in the process flow 200 as shown in FIG. 22. In accordance with some embodiments, dummy dielectric layer 38 is formed through a deposition process, which may include Chemical Vapor Deposition (CVD), Atomic Layer Deposition (ALD), or the like. The material of dummy dielectric layer 38 may include silicon oxide, while other dielectric materials such as silicon nitride, silicon carbo-nitride, silicon oxynitride, or the like, may also be used.

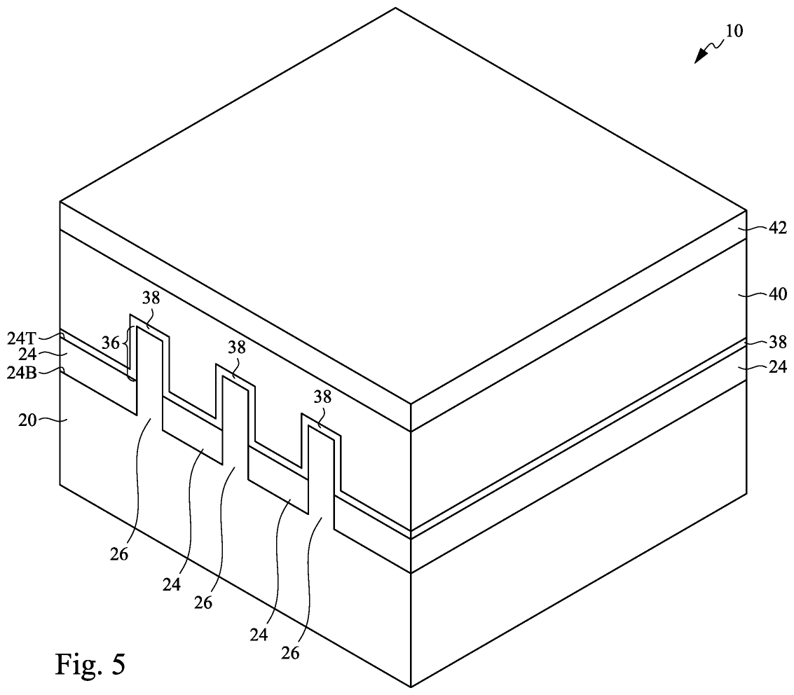

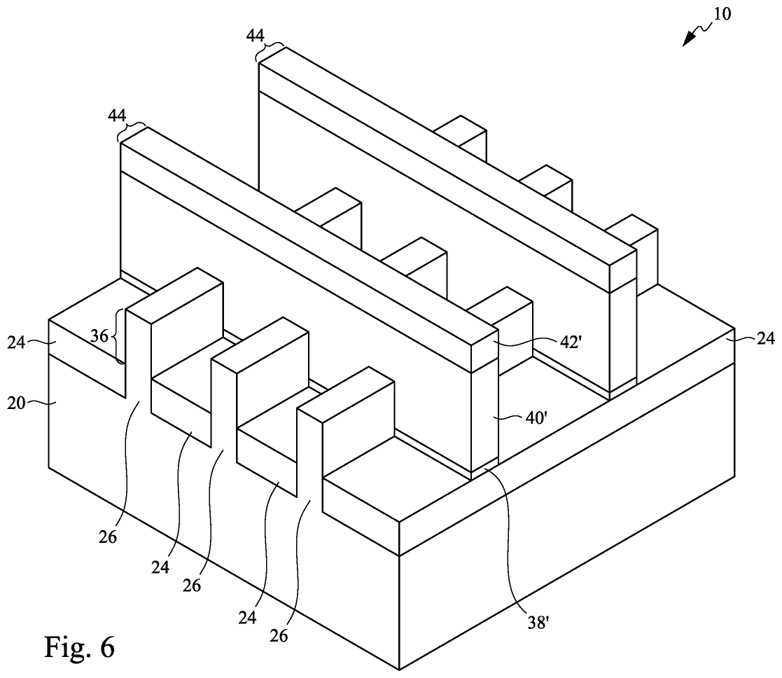

FIG. 5 illustrates the deposition of dummy gate electrode layer 40. The respective process is illustrated as process 208 in the process flow 200 as shown in FIG. 22. Dummy gate electrode layer 40 may be formed of or comprise polysilicon or amorphous silicon, while other materials may also be used. The formation process may include a deposition process followed by a planarization process. Hard mask layer 42 is then deposited on dummy gate electrode layer 40. The respective process is illustrated as process 212 in the process flow 200 as shown in FIG. 22. Hard mask layer 42 may be formed of or comprise silicon nitride, silicon oxide, silicon oxy-carbo-nitride, or multi-layers thereof.

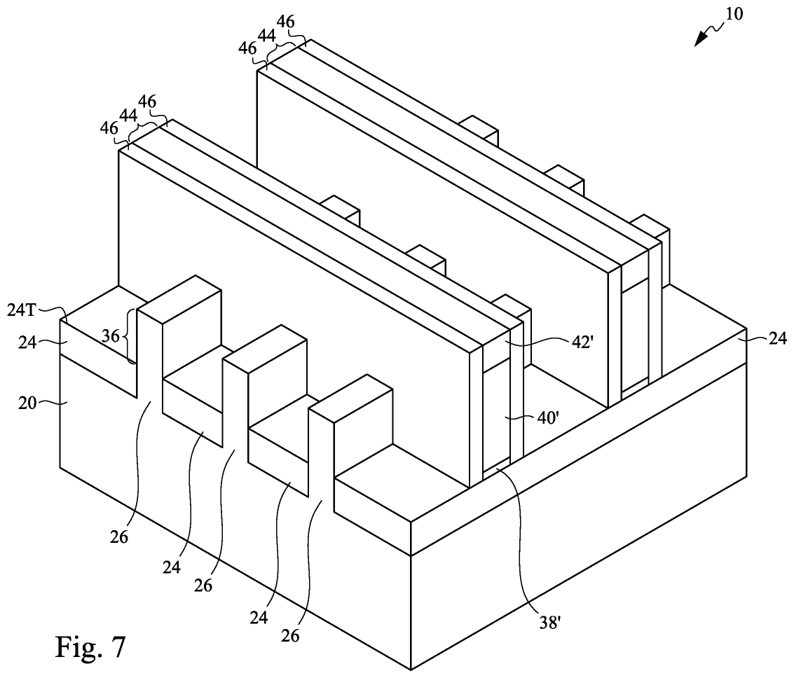

FIG. 6 illustrates the patterning process for forming dummy gate stacks 44. The respective process is illustrated as process 210 in the process flow 200 as shown in FIG. 22. In accordance with some embodiments, hard mask layer 42 is first patterned, for example, using a patterned photoresist (not shown) as an etching mask. The resulting hard masks are referred to as hard masks 42′. Hard masks 42′ are then used as an etching mask to etch the underlying dummy gate electrode layer 40 in order to form dummy gate electrodes 40′. The etching is performed using an anisotropic etching process.

In accordance with alternative embodiments, the patterning of dummy gate electrode layer 40 stops on dummy gate dielectric layer 38, and dummy gate dielectric layer 38 is not patterned. The subsequently formed gate spacers will be formed on the un-patterned dummy gate dielectric layer 38.

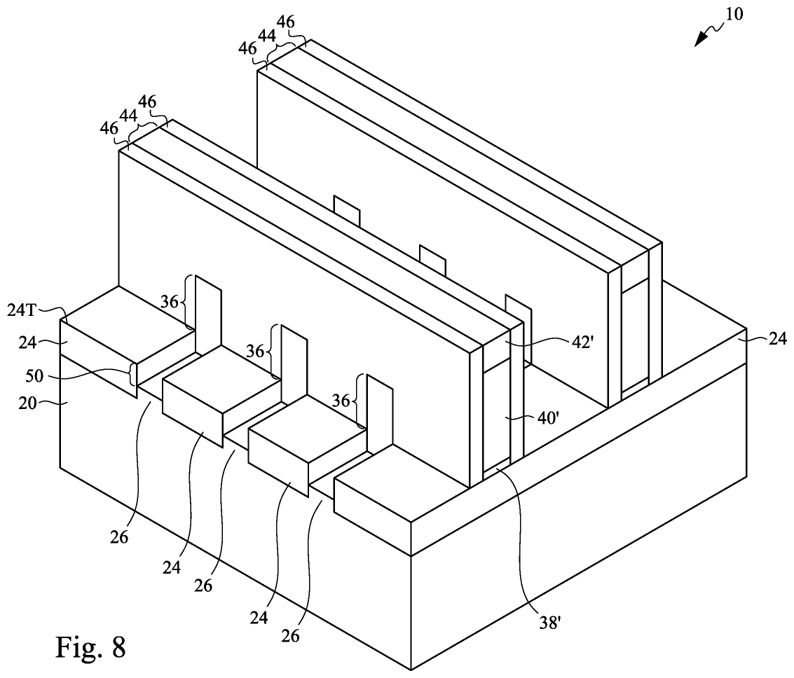

Next, as shown in FIG. 7, gate spacers 46 are formed on the sidewalls of dummy gate stacks 44. The respective process is illustrated as process 212 in the process flow 200 as shown in FIG. 22. In accordance with some embodiments, gate spacers 46 are formed of a dielectric material(s) such as silicon nitride, silicon carbo-nitride, or the like, and may have a single-layer structure or a multi-layer structure including a plurality of dielectric layers.

Referring to FIG. 8, an etching process(es) is performed to recess protruding fins 36. The respective process is illustrated as process 214 in the process flow 200 as shown in FIG. 22. If there are any portions of dummy gate dielectric layer 38 not directly underlying dummy gate stacks 44 and gate spacers 46, the exposed portions of dummy gate dielectric layer 38 are also removed. The portions of protruding fins 36 that are not covered by dummy gate stacks 44 and gate spacers 46 are also etched. The recessing may be anisotropic, and hence the portions of protruding fins 36 directly underlying dummy gate stacks 44 and gate spacers 46 are protected, and are not etched. The top surfaces of the recessed semiconductor strips 26 may be lower than the top surfaces 24T of STI regions 24 in accordance with some embodiments. Recesses 50 are accordingly formed. Recesses 50 comprise some portions located on the opposite sides of dummy gate stacks 44, and some portions between remaining portions of protruding fins 36. There may be, or may not be, fin spacers left on the opposite sides of recesses 50, which fin spacers are not illustrated.

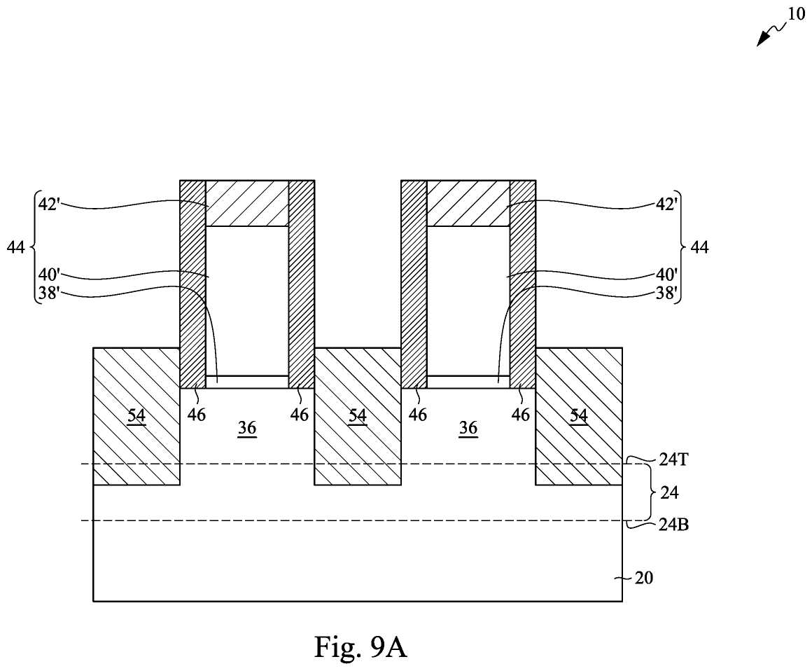

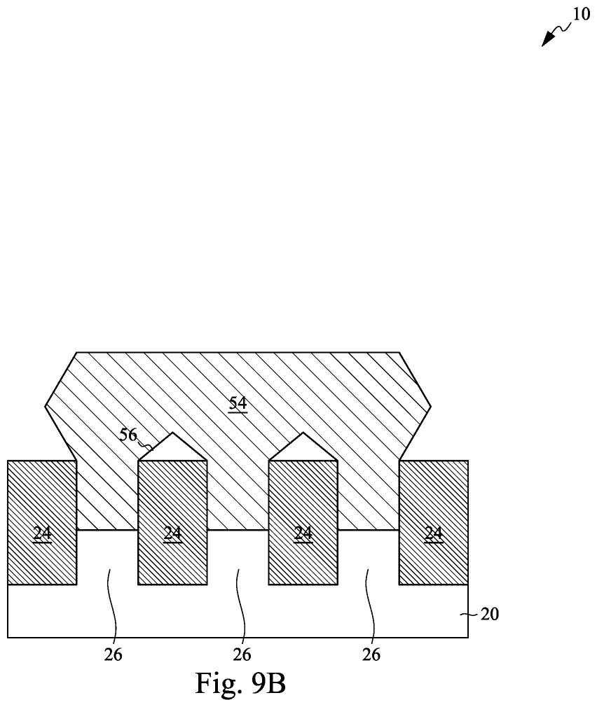

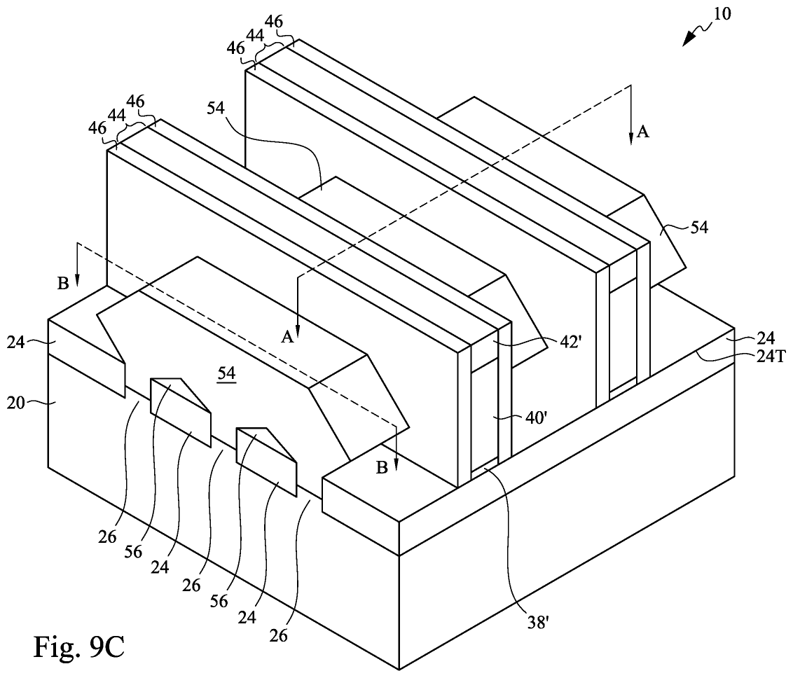

Next, as shown in FIG. 9C, epitaxy regions (source/drain regions) 54 are formed by selectively growing (through epitaxy) a semiconductor material starting from recesses 50. The respective process is illustrated as process 216 in the process flow 200 as shown in FIG. 22. FIGS. 9A and 9B illustrate the vertical cross-sections 9A-9A and 9B-9B, respectively, of the structure shown in FIG. 9C.

Depending on whether the resulting FinFET is a p-type FinFET or an n-type FinFET, different materials may be grown in the epitaxy. For example, when the resulting FinFET is a p-type FinFET, silicon germanium boron (SiGeB), silicon boron (SiB), or the like may be grown. Conversely, when the resulting FinFET is an n-type FinFET, silicon phosphorous (SiP), silicon carbon phosphorous (SiCP), or the like may be grown. In accordance with alternative embodiments, epitaxy regions 54 comprise III-V compound semiconductors such as GaAs, InP, GaN, InGaAs, InAlAs, GaSb, AlSb, AlAs, AIP, GaP, combinations thereof, or multi-layers thereof.

After Recesses 50 are filled with epitaxy regions 54, the further epitaxial growth of epitaxy regions 54 may cause epitaxy regions 54 to expand horizontally, and facets may be formed. The further growth of epitaxy regions 54 may also cause neighboring epitaxy regions 54 to merge with each other. Voids (air gaps) 56 may be generated. After the epitaxy step, epitaxy regions 54 may be further implanted with a p-type or an n-type impurity, which are also denoted using reference numeral 54. In accordance with alternative embodiments, the implantation step is skipped when epitaxy regions 54 are in-situ doped with the p-type or n-type impurity during the epitaxy.

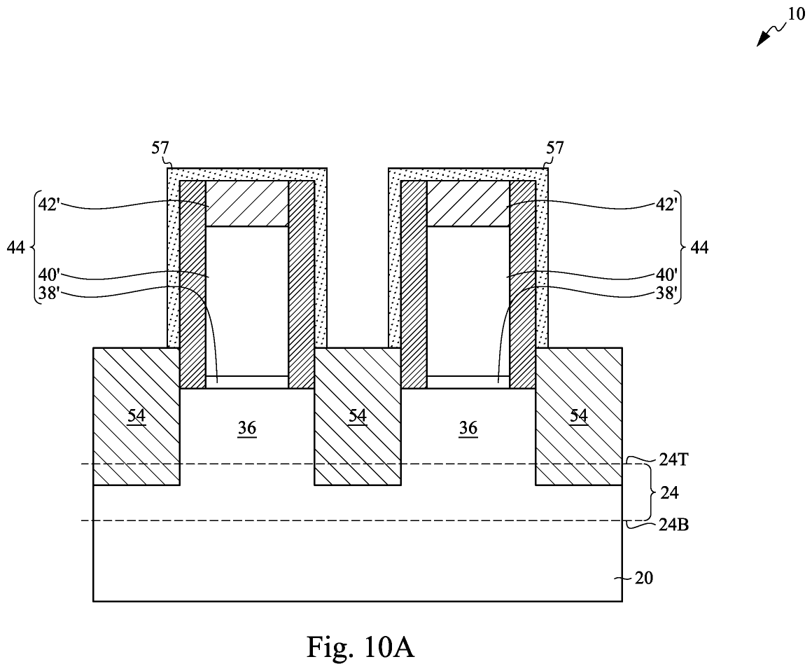

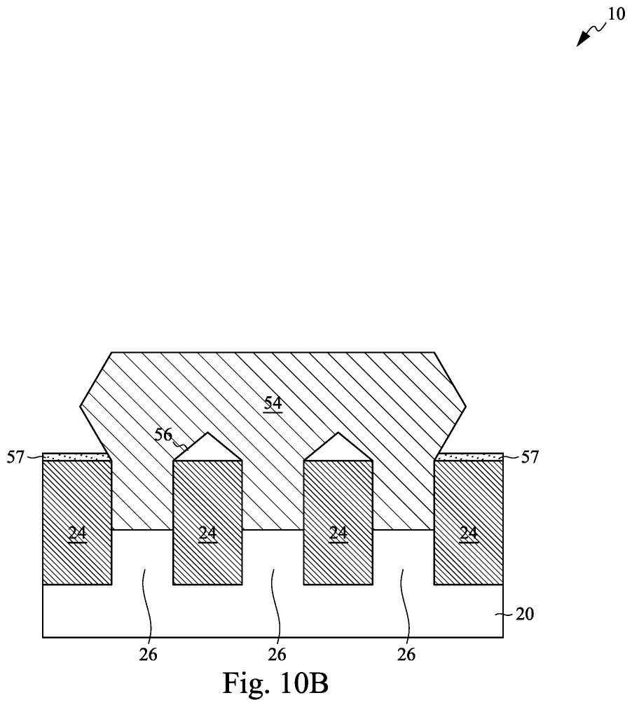

Next, as shown in FIGS. 10A and 10B, inhibitor film 57 is selectively formed. The respective process is illustrated as process 218 in the process flow 200 as shown in FIG. 22. In accordance with some embodiments, inhibitor film 57 is formed through a deposition process, in which wafer 10 is exposed to and soaked in a process gas (precursor) in order to have the inhibitor film 57 deposited thereon. The deposition is performed without turning on plasma. The deposition temperature may be in the range between about 50° C. and about 300° C., or in the range between about 50° C. and about 200° C., depending on the process gas. The deposition time may be in the range between about 30 seconds and about 60 minutes. In the deposition, the flow rate of the process gas may be in the range between about 500 sccm and about 10,000 sccm.

The process gas may include a silane-based material, an amine-based material, a phosphate-based material, and/or a thiol-based material. The example process gases may include a Si—Cl based process gas including Octadecyltrichlorosilane (CH₃(CH₂)₁₇SiCl₃), Trichloro (1H,1H,2H,2H-perfluorooctyl) silane (CF₃(CF₂)₅(CH₂)₂SiCl₃), Dimethyl dichlorosilane ((CH₃)₂SiCl₂), (Dimethylamino) trimethylsilane ((CH₃)₂NSi(CH₃)₃), 1-(Trimethylsilyl) pyrrolidine ((CH₃)₃Si—NC₄H₈), Hexamethyl disilazane ([(CH₃)₃Si]₂NH), Bis(dimethylamino)dimethylsilane ([(CH₃)₂N]₂Si(CH₃)₂), or the like, or the combinations thereof.

In accordance with alternative embodiments, inhibitor film 57 is formed by soaking wafer 10 in a chemical solution, in which one or more above-discussed chemical or a Si—N based chemical is dissolved in a solvent. The solvent may include acetone or Isopropyl alcohol (IPA). In some other embodiments, the solvent may include demineralized water. The soaking time may be in the range between about 30 seconds and about 60 minutes.

In accordance with some embodiments, the exposed dielectric materials of wafer 10, which dielectric materials which may comprise silicon and/or oxide, have OH bonds at their surfaces. The exposed materials may be comprised in gate spacers 46, hard masks 42′, and STI regions 24. In the formation of inhibitor film 57, the OH bonds are broken, and the oxygen atoms on the surfaces of the exposed dielectric materials are bonded to the molecules in the precursor for forming inhibitor film 57. The functional groups in the precursor are accordingly attached to the oxygen in the underlying dielectric layers such as gate spacers 46, hard masks 42′, and STI regions 24, hence forming inhibitor film 57.

On source/drain regions 54, however, no OH bonds exist, and such reaction does not occur on source/drain regions 54 even though source/drain regions 54 are also exposed to the same precursor. Accordingly, inhibitor film 57 is selectively formed on the top surfaces and sidewalls of the exposed semiconductor regions such as gate spacers 46, hard masks 42′, and STI regions 24, but not on source/drain regions 54. Inhibitor film 57 may be formed as a self-assembled-monolayer (SAM). The respective process may also be referred to as a SAM process, in which the precedingly attached molecules terminate the dangling bonds of oxygen, and hence there may not be more layers of the inhibitor film 57 formed thereon. The formation of inhibitor film 57 thus may be self-terminating. Depending on the sizes of the attached molecules, inhibitor film 57 may have a thickness in the range between about 0.3 nm and about 2 nm.

Inhibitor film 57 is thus formed/deposited selectively. Also, inhibitor film 57 may be an organic film, and may include functional groups CH₃, CH₂, CF₂, or the combinations thereof. Inhibitor film 57 may also include a carbon chain (and the chain of CH₃), in which a plurality of carbon atoms are connected to form the chain.

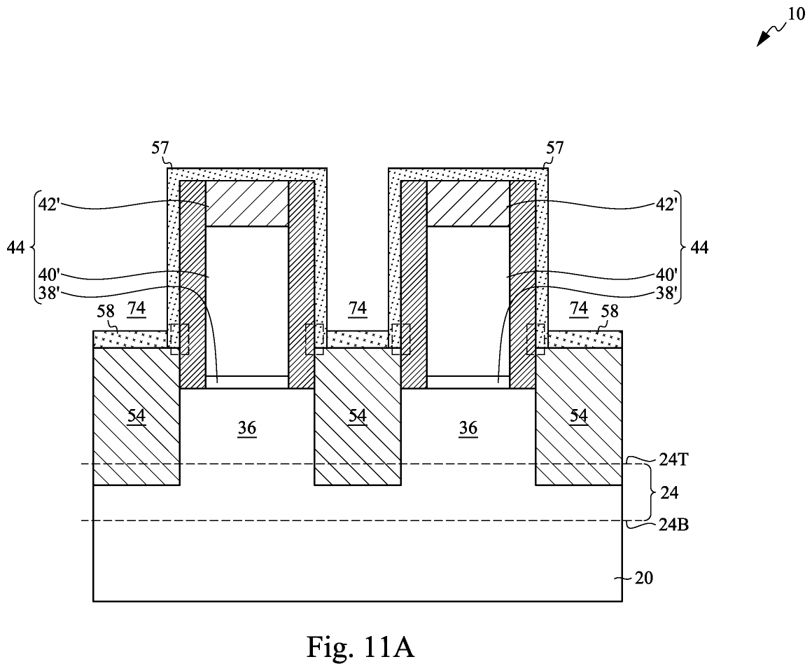

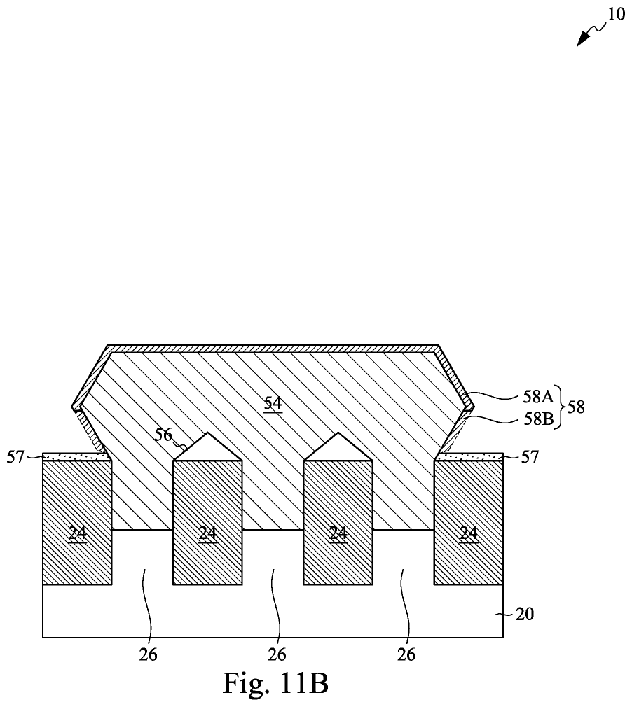

FIGS. 11A and 11B illustrate the selective deposition of contact etch stop layer (CESL) 58 in accordance with some embodiments. The respective process is illustrated as process 220 in the process flow 200 as shown in FIG. 22. CESL 58 is also an etch stop layer for stopping the etching in a subsequent process. In accordance with some embodiments, the formation process may include a thermal deposition process such as a Chemical Vapor Deposition (CVD) process, an Atomic Vapor Deposition (CVD) process, or the like. The deposited CESL 58 may comprise silicon nitride, silicon carbo-nitride, silicon oxy-carbo-nitride, or the like, with the corresponding precursors conducted to result in the reaction.

Due to the existence of inhibitor film 57, CESL 58 is selectively grown on where inhibitor film 57 is not formed, and thus is formed on source/drain regions 54. In accordance with some embodiments, as shown in FIG. 11B, source/drain regions 54 may include the surfaces facing upwardly, and may or may not include surfaces facing downwardly. The downward facing surfaces may be the surfaces of downward facing facets.

In accordance with some embodiments, depending on the deposition method and the process conditions, the formation of CESL 58 is conformal, and hence both of upward-facing and downward-facing surfaces have CESL 58 grown thereon. In accordance with alternative embodiments, the upward-facing surfaces of source/drain regions 54 have CESL 58A grown thereon, while some parts or all parts of the downward facing surfaces of source/drain regions 54 have no CESL thereon. Accordingly, the portions 58B of CESL 58 are marked as being dashed to indicate that these portions may or may not be formed.

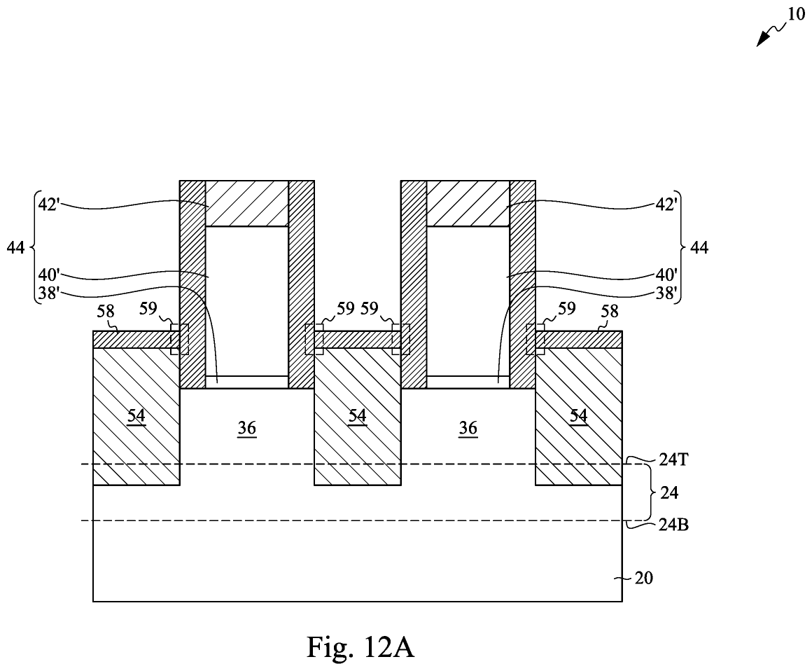

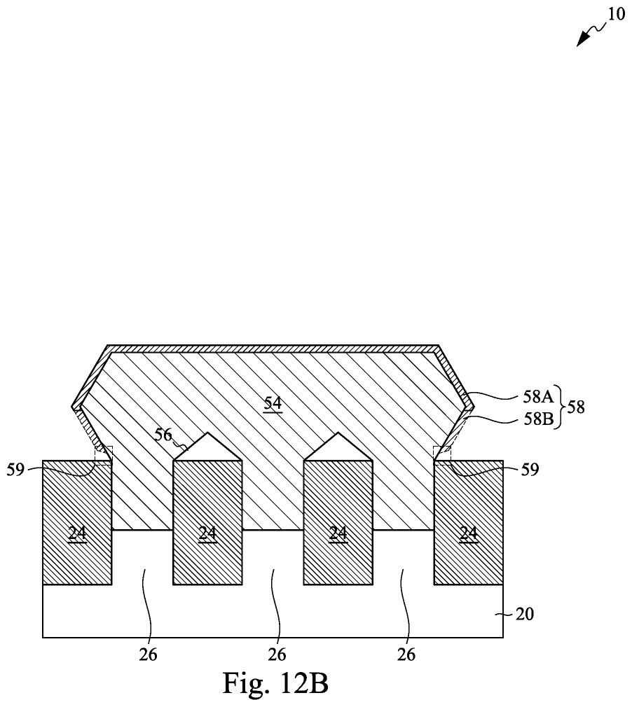

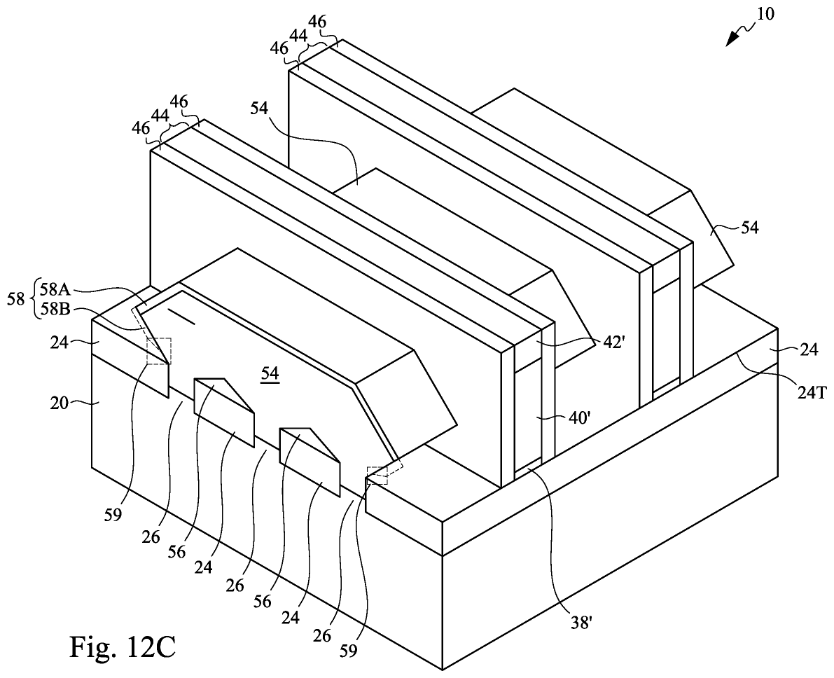

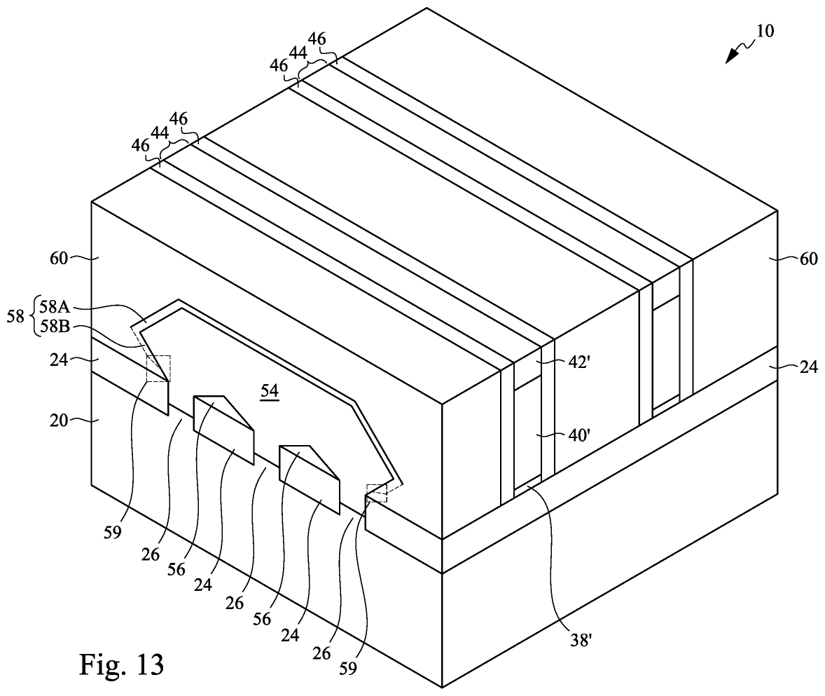

Next, inhibitor film 57 is removed. The respective process is illustrated as process 222 in the process flow 200 as shown in FIG. 22. FIGS. 12A, 12B, and 12C illustrate the resulting structure. Depending on the thickness of inhibitor films 57, CESL 58 may or may not extend into regions 59, which was previously occupied by inhibitor films 57. Alternatively stated, CESL 58 may be spaced apart from the nearest dielectric features by the spacings in regions 59. In accordance with some embodiments, the removal of inhibitor film 57 is performed through a thermal process. For example, the temperature may be higher than about 200° C. or higher than about 300° C. Process gases including O₂, H₂, N₂, or the like, or combinations thereof, may be used. As a result, inhibitor film 57 is decomposed as gases, and are removed.

FIG. 13 illustrates the perspective view in the formation of Inter-Layer Dielectric (ILD) 6O. The respective process is illustrated as process 224 in the process flow 200 as shown in FIG. 22. ILD 60 may include a dielectric material formed using, for example, FCVD, spin-on coating, CVD, or another deposition method. ILD 60 may be formed of an oxygen-containing dielectric material, which may be a silicon-oxide based material such as silicon oxide, Phospho-Silicate Glass (PSG), Boro-Silicate Glass (BSG), Boron-Doped Phospho-Silicate Glass (BPSG), or the like. A planarization process such as a CMP process or a mechanical grinding process may be performed to level the top surfaces of ILD 60, dummy gate stacks 44, and gate spacers 46 with each other. Due to the selective formation of the CESL 58, ILD 60 may be in physical contact with the top surfaces of STI regions 24. As shown in FIG. 13, ILD 60, at the bottoms of the downward-facing facets of source/drain regions 54, ILD may be in physical contact with source/drain regions 54.

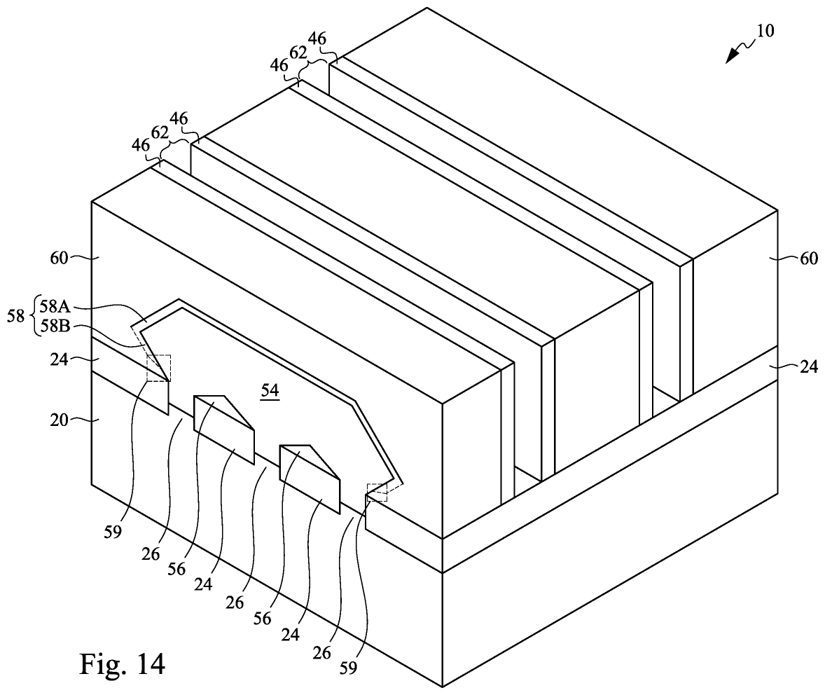

Hard masks 42′, dummy gate electrodes 40′ and dummy gate dielectrics 38′ are then removed, forming trenches 62 between gate spacers 46, as shown in FIG. 14. The respective process is illustrated as process 226 in the process flow 200 as shown in FIG. 22. In accordance with some embodiments, the removal of dummy gate electrodes 40′ is performed using an anisotropic etching process, similar to the patterning process as shown in FIG. 6. In accordance with alternative embodiments, the removal of dummy gate electrodes 40′ is performed using an isotropic etching process, which may be a wet etching process or a dry etching process. After the removal of dummy gate electrodes 40′, dummy gate dielectrics 38′ are revealed through trenches 62.

Next, dummy gate dielectrics 38′ are removed. In accordance with some embodiments, the etching process may be anisotropic, and the process gas may include the mixture of NF₃ and NH₃, or the mixture of HF and NH₃. The etching process may include isotropic effect and some anisotropic effect to ensure the removal of the sidewall portions of dummy gate dielectrics 38′. In accordance with alternative embodiments, an isotropic etching process such as a wet etching process may be used. For example, a HF solution may be used. The top surfaces and the sidewalls of protruding semiconductor fins 36 are thus exposed to trenches 62, as shown in FIG. 14.

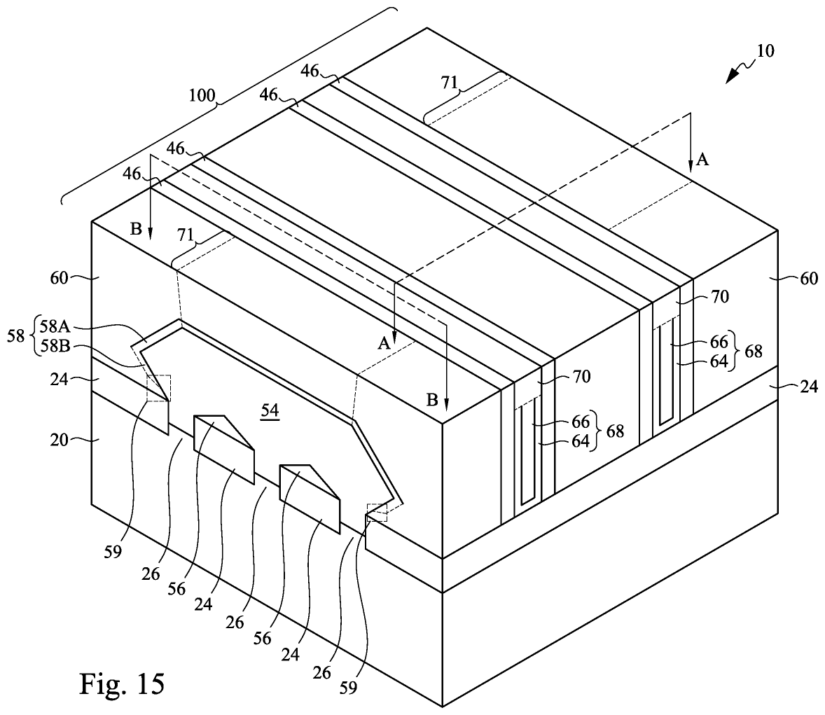

Next, as shown in FIG. 15, replacement gate stacks 68 are formed. The respective process is illustrated as process 228 in the process flow 200 as shown in FIG. 22. In accordance with some embodiments, replacement gate stacks 68 include gate dielectrics 64 and gate electrodes 68. Gate dielectrics 64 may further include Interfacial Layer (ILs) and high-k dielectrics over the ILs. In accordance with some embodiments, the formation of the ILs is formed through an oxidation process. The ILs may include silicon oxide (SiO₂). In accordance with some embodiments, the ILs are deposited. Next, the high-k dielectric layers are deposited over the ILs. The high-k dielectric layers include a high-k dielectric material such as hafnium oxide, lanthanum oxide, aluminum oxide, zirconium oxide, or the like.

Gate electrodes 66 are formed on and contacting gate dielectrics 64. A gate electrode 66 may include stacked layers, which may include a diffusion barrier layer (a capping layer, not shown), and one or more work-function layer over the diffusion barrier layer. The diffusion barrier layer may be formed of TIN, TiSiN, or the like.

The work-function layer determines the work-function of the gate electrode 66, and includes at least one layer, or a plurality of layers formed of different materials. The material of the work-function layer may be selected according to whether the respective FinFET is an n-type FinFET or a p-type FinFET. For example, when the FinFET is an n-type FinFET, the work-function layer may include a TaN layer and a titanium aluminum (TiAl) layer over the TaN layer. When the FinFET is a p-type FinFET, the work-function layer may include a TaN layer and possibly a TiN layer.

After the deposition of the work-function layer, a blocking layer (such as a TiN layer), and a metal-filling region are deposited to fully fill trenches 62. Next, a planarization process such as a CMP process or a mechanical grinding process is performed, so that the top surface of gate stack 68 is coplanar with the top surface of ILD 60. FinFET 100 is thus formed.

In accordance with some embodiments, as shown in FIG. 15, replacement gate stacks 68 are etched back, resulting in recesses to be formed between opposite gate spacers 46. Next, hard masks 70 are formed over replacement gate stacks 68. Hard masks 70 are self-aligned to the underlying gate stacks 68. The respective process is illustrated as process 230 in the process flow 200 as shown in FIG. 22. In accordance with some embodiments, the formation of hard masks 70 includes a deposition process to form a blanket dielectric material, which fills the recesses, and a planarization process to remove the excess dielectric material over gate spacers 46 and ILD 60. Hard masks 70 may be formed of silicon nitride, for example, or other like dielectric materials. In accordance with alternative embodiments, replacement gate stacks 68 are not recessed, and hard masks 70 are not formed. Accordingly, hard masks 70 are illustrated as being dashed to indicate that hard masks 70 may or may not be formed.

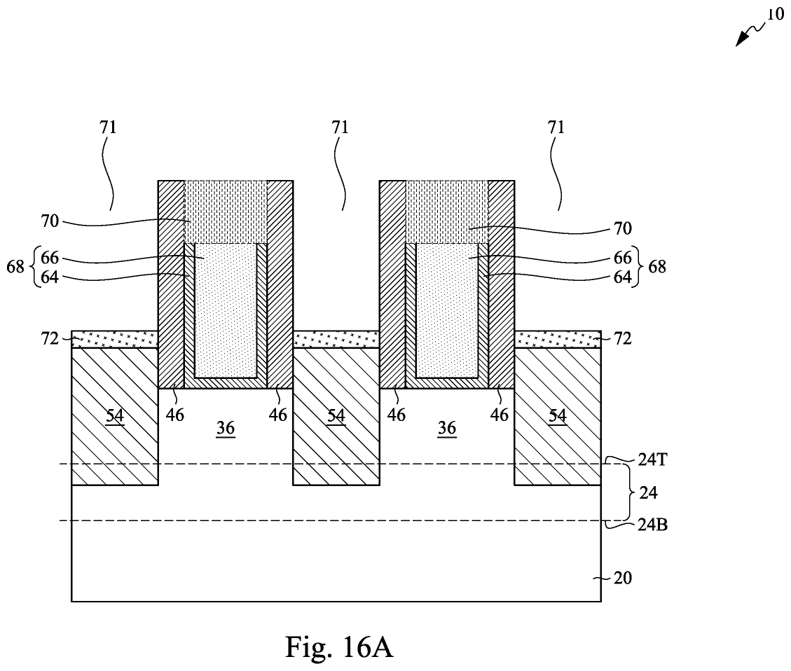

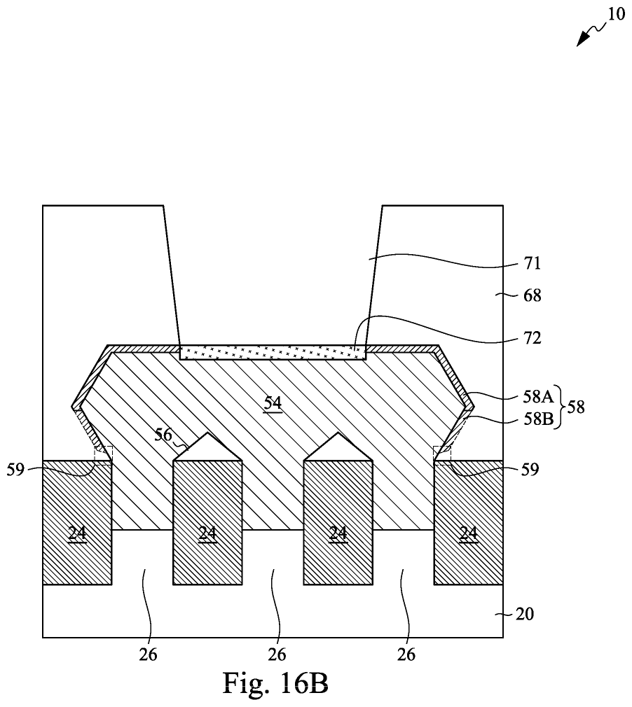

In subsequent processes, ILD 60 and CESL 58 are etched to form source/drain contact openings 71, as shown in FIGS. 16A and 16B. The respective process is illustrated as process 232 in the process flow 200 as shown in FIG. 22. The positions of source/drain contact openings 71 are illustrated in FIG. 15 also. In the formation process, an etching process is performed to etch ILD 60 and to form source/drain contact openings 71, and the etching stops on CESL 58. Next, CESL 58 is etched to reveal the underlying source/drain regions 54.

In a subsequent process, as also shown in FIGS. 16A and 16B, source/drain silicide layers 72 are formed. The respective process is illustrated as process 234 in the process flow 200 as shown in FIG. 22. The formation process may include depositing a metal layer extending into openings 71 to contact source/drain regions 54, performing an annealing process to react the metal layer with source/drain regions 54 and to form source/drain silicide layers 72, and removing the metal layer.

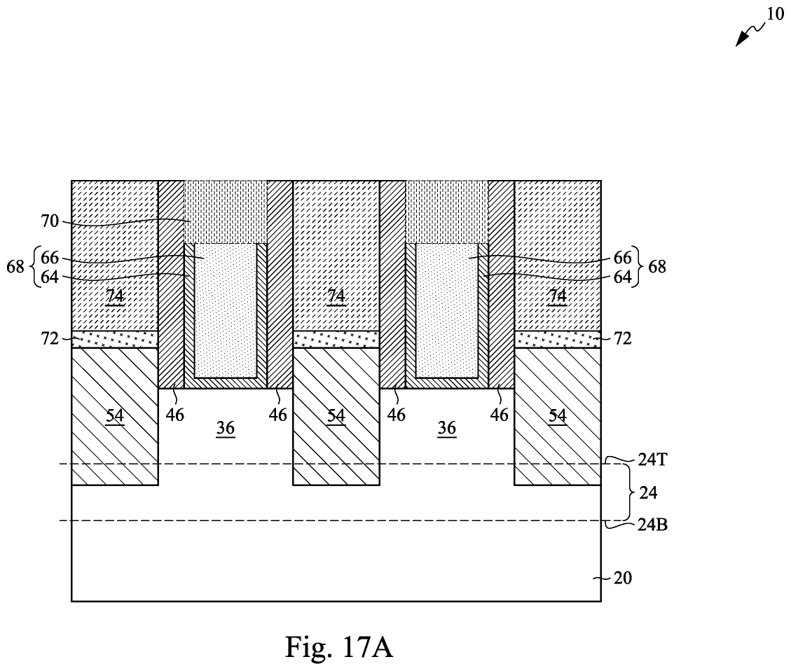

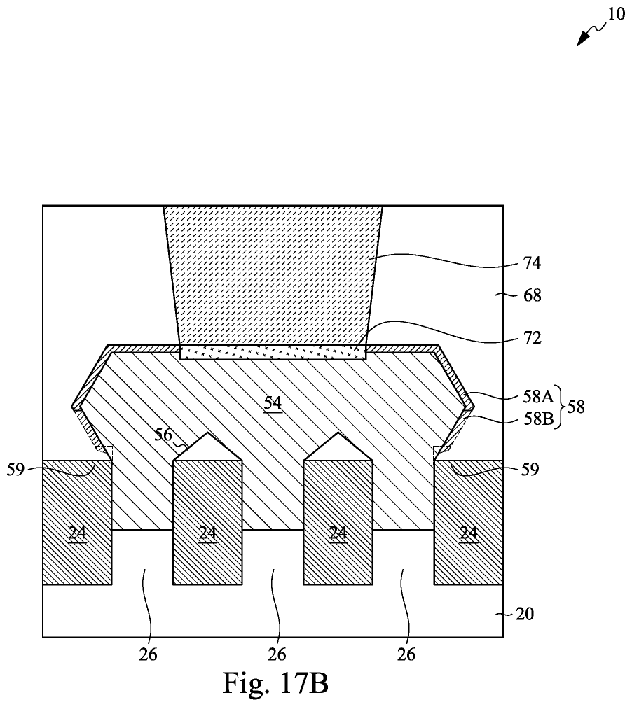

FIGS. 17A and 17B illustrate the formation of (lower) source/drain contact plugs 74. The respective process is illustrated as process 236 in the process flow 200 as shown in FIG. 22. In accordance with some embodiments, the formation process may include depositing a conductive material, which may include a metallic material such as tungsten, cobalt, or the like, and performing a CMP process to remove excess portions of the metallic material. A conductive barrier such as a TiN layer may be (or may not be) formed before the conductive material is deposited.

In accordance with some embodiments, due to the selective formation of CESL 58, the CESL 58 does not include vertical portions on the sidewalls of gate spacers 46 (FIGS. 12A and 12C). This has two benefits. First, if CESL 58 has vertical portions on the sidewalls of gate spacers 46, the vertical portions will occupy the space that otherwise may be used by source/drain contact plugs 74, resulting in the increase in the resistance of source/drain contact plugs 74. Accordingly, by selectively forming CESL 58, the source/drain contact plugs 74 are formed wider and hence have lower resistance.

Furthermore, the CESL 58 has a higher dielectric constant (k value) than that of ILD 60. For example, ILD 60 may have a k value in the range between about 3.1 and about 3.9. The CESL 58, on the other hand, may have a k value between about 4 and about 7. By not forming the vertical portions of the CESL 58, the parasitic capacitance between source/drain contact plugs 74 and gate electrode 66 is reduced.

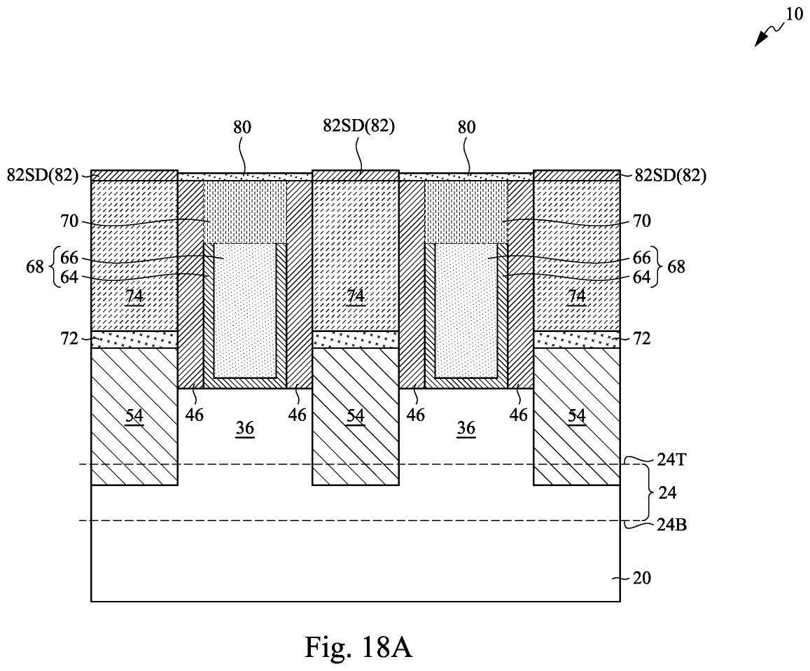

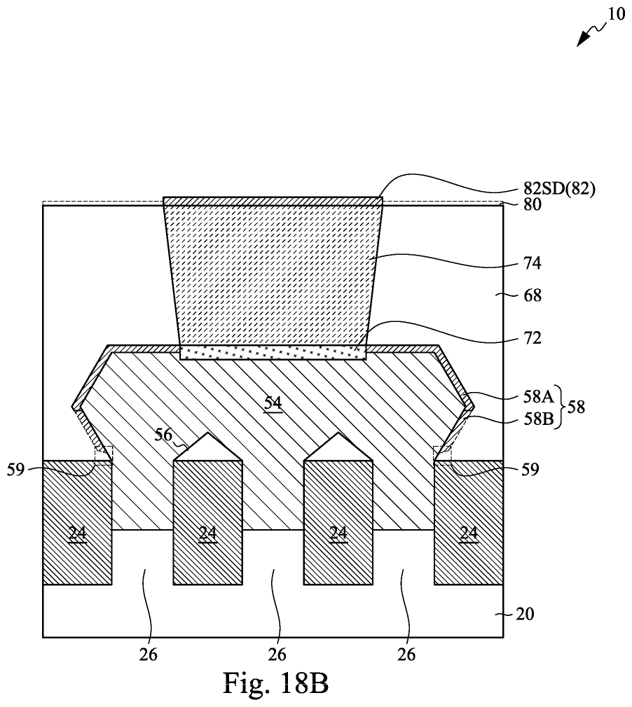

FIGS. 18A and 18B illustrate the selective formation of inhibitor film 80 on dielectric materials (which may have OH groups at surfaces) in accordance with some embodiments. The respective process is illustrated as process 238 in the process flow 200 as shown in FIG. 22. In accordance with some embodiments, the precursors, the materials and the formation processes of inhibitor film 80 may be selected from the same groups of the candidate precursors, the candidate materials and the candidate formation processes, respectively, of inhibitor film 57, and thus are not repeated. As shown in FIGS. 18A and 18B, inhibitor film 80 are formed on ILD 60. Inhibitor film 80 may be formed on hard masks 70 when hard masks 70 are formed. Inhibitor film 80 may or may not be formed on top of gate spacers 46, depending on the material of gate spacers 46. On the other hand, inhibitor film 80 is not formed on source/drain contact plugs 74.

Next, as also shown in FIGS. 18A and 18B, CESL 82 (which is also an etch stop layer, also denoted as 82SD) is selectively deposited. The respective process is also illustrated as process 238 in the process flow 200 as shown in FIG. 22. Due to the existence of inhibitor film 80, CESL 82 is selectively deposited where inhibitor film 80 is not formed. Accordingly, CESL 82 is selectively formed on source/drain contact plugs 74. In accordance with some embodiments in which inhibitor film 80 is not formed on the top surface of gate spacers 46, CESL 82 will also be formed on the top surface of gate spacers 46. Otherwise, the top surface of gate spacers 46 have no CESL 82 formed thereon, as shown in FIG. 18A.

After the formation of CESL 82, inhibitor film 80 is removed, for example, in a thermal process using H₂, N₂, and/or O₂ as process gases. The respective process is illustrated as process 240 in the process flow 200 as shown in FIG. 22.

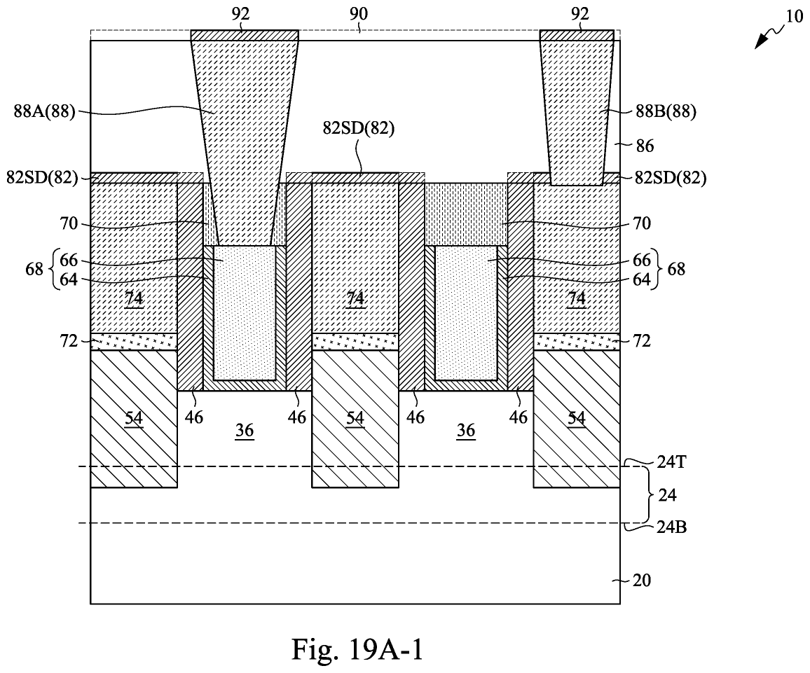

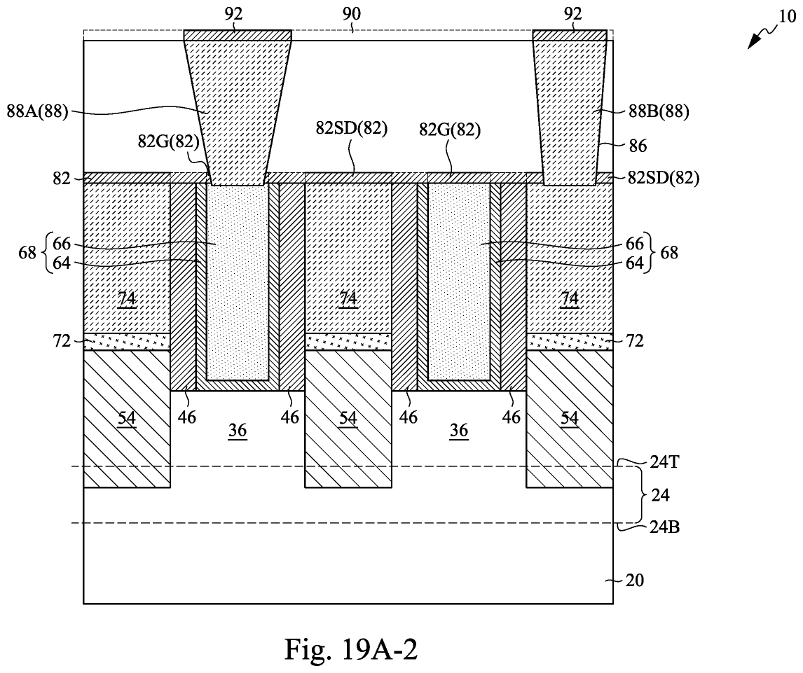

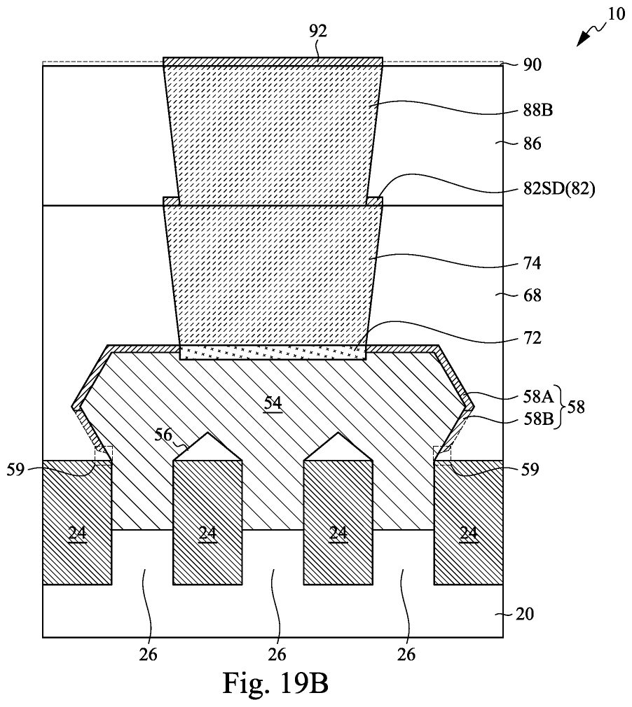

FIG. 19A-1 illustrates a cross-sectional view in the formation of ILD 86 and contact plugs 88 (including gate contact plug 88A and source/drain contact plug 88B) in accordance with some embodiments. The respective process is illustrated as process 242 in the process flow 200 as shown in FIG. 22. In accordance with these embodiments in which hard masks 70 are formed, inhibitor film 80 (FIG. 18A) will be formed over hard masks 70, and accordingly, CESL 82 (which is also denoted as CESL 82SD) will not be formed on hard masks 70. ILD 86 is thus in physical contact with hard masks 70. The dashed portions of CESL 82 represent that CESL 82 may be, or may not be, formed on to of gate spacers 46.

In a subsequent process, contact plugs 88 (including gate contact plugs 88A and source/drain contact plugs 88B) are formed. The formation process may include etching ILD 86, hard masks 70, and CESL 82SD to form openings, filling the openings with conductive materials (such as tungsten, cobalt, copper, TiN, and/or the like), and performing a planarization process to remove excess portions of the conductive materials.

In subsequent processes, etch stop layer 92 may be selectively formed on contact plugs 88A and 88B. The formation may include selectively forming inhibitor film 90 on ILD 86, but not on contact plugs 88, and selectively depositing etch stop layer 92 where inhibitor film 90 is not formed. Inhibitor film 90 may then be removed. An inter-metal dielectric (IMD) layer (not shown), which may be a low-k dielectric layer, may then be formed over CESL 82 and ILD 86. Metal vias (which may be a single-damascene structure or a part of a dual-damascene structure) are then formed to penetrate through the IMD layer and the etch stop layer 92.

FIG. 19A-2 illustrates an embodiment in which replacement gate stacks 68 are not recessed, and hard masks 70 are not formed. Accordingly, inhibitor film (refer to FIG. 18A) will not be formed on replacement gate electrodes 66, allowing CESL 82 (which is also denoted as CESL 82G, FIG. 19A-2) to be formed directly over and vertically aligned to replacement gate electrodes 66. Gate contact plug 88A and source/drain contact plug 88B accordingly penetrate through portions 82G and 82SD, respectively, of CESL 82 to contact gate electrode 66 and source/drain contact plug 74, respectively.

FIG. 19B illustrates a cross-sectional view, in which the source/drain contact plug 74 is illustrated. Etch stop layer 92 is also selectively formed over source/drain contact plug 88B, and formed where inhibitor film 90 is not formed.

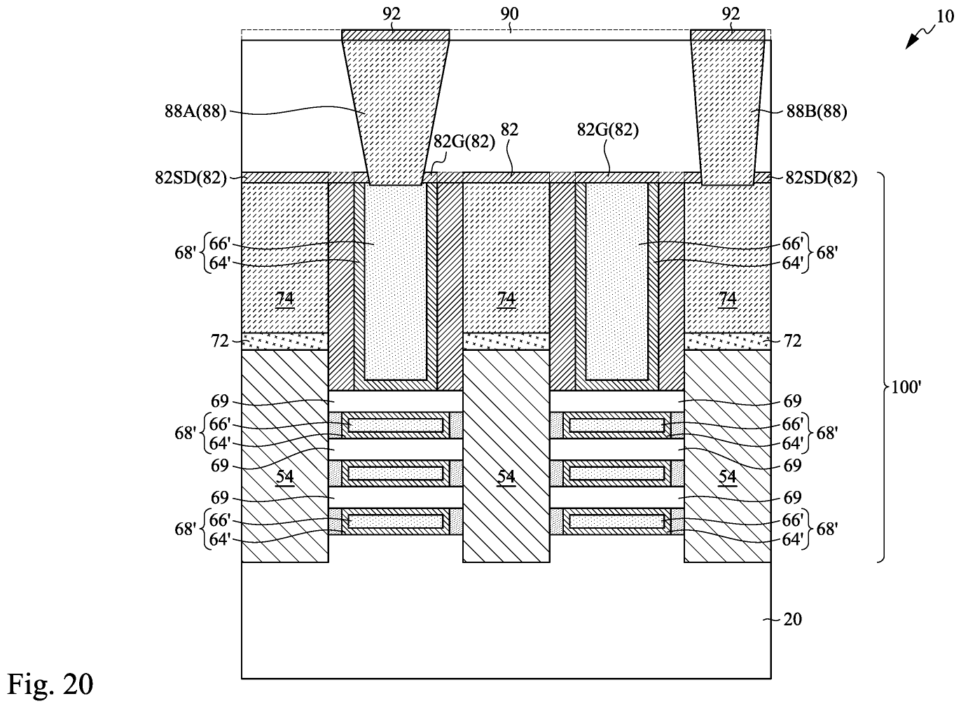

FIG. 20 illustrates an embodiment in which the selective formation of CESL and etch stop layer by adopting inhibitor films is applied to a GAA transistor 100′ in accordance with some embodiments. The structure shown in FIG. 20 is obtained from the cross-section passing through replacement gate stack 68′, which includes gate dielectrics 64′ and gate electrodes 66′. Semiconductors nanostructures 69 are encircled by gate stacks 68′ to act as the channels. The structures of the source/drain regions 54 of the GAA transistor 100′ are essentially the same as shown in FIGS. 16B, 17B, 18B, and 19B.

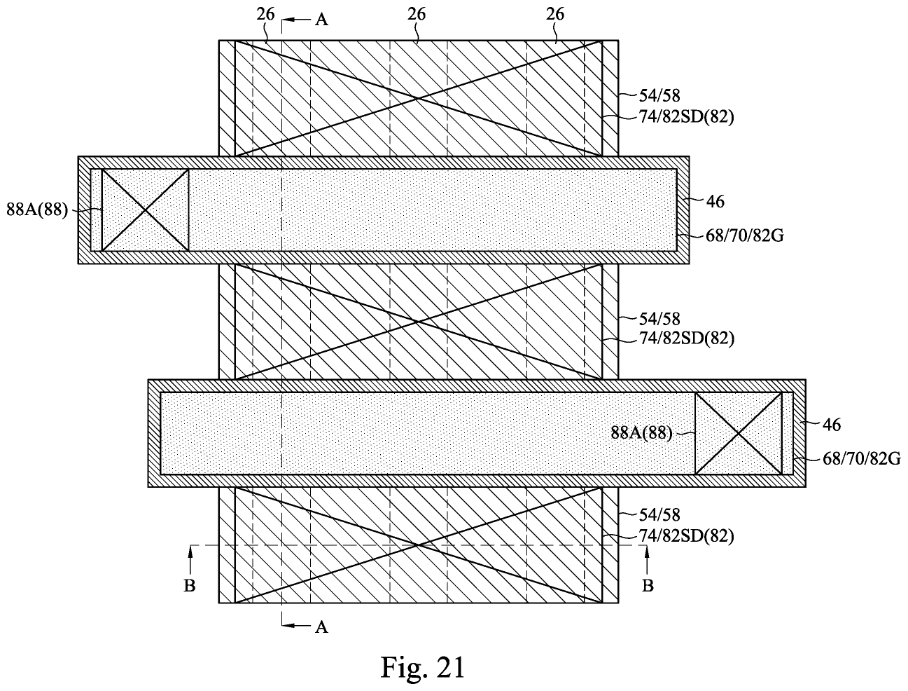

FIG. 21 illustrates a top view of the transistor 100 in accordance with some embodiments. The cross-sectional view in FIG. 19A-1 or FIG. 19A-2 may be obtained from cross-section A-A in FIG. 21 (also refer to cross-section A-A in FIG. 15). Gate contact plug 88A is also illustrated in the cross-sectional view in FIG. 19A-1 or FIG. 19A-2, although they may be outside of the cross-section as shown in FIG. 21. The cross-sectional view in FIG. 19B may be obtained from cross-section B-B in FIG. 21 (also refer to cross-section B-B in FIG. 15).

The embodiments of the present disclosure have some advantageous features. By selectively forming etch stop layers (which include contact etch stop layers and other etch stop layers) on the features to which contacts are to be made, but not on the surrounding dielectric layers, the sizes of the etch stop layers are reduced. Since the etch stop layers may have higher k values than nearby inter-layer dielectrics, reducing the sizes of the etch stop layers results in the reduction of parasitic capacitance. Furthermore, the reduction in the size of the selectively formed etch stop layers yield some space for forming contact plugs, and the resistance of the contact plugs is reduced.

In accordance with some embodiments, a method comprises forming a gate stack over a semiconductor region; performing an epitaxy process to form a source/drain region aside of the gate stack; forming a source/drain contact plug over and electrically coupling to the source/drain region; forming a gate contact plug over and electrically coupling to the gate stack; selectively forming a first inhibitor film on a dielectric layer nearby a conductive feature, wherein the conductive feature is selected from the group consisting of the source/drain region, the source/drain contact plug, and the gate contact plug; selectively depositing a first etch stop layer on the conductive feature, wherein the first inhibitor film prevents the first etch stop layer from being deposited thereon; and removing the first inhibitor film.

In an embodiment, the conductive feature comprises the source/drain region, and wherein the first inhibitor film comprises a portion on a shallow trench isolation nearby the source/drain region. In an embodiment, the structure further comprises selectively forming a second inhibitor film on a second dielectric layer nearby the source/drain contact plug; selectively depositing a second etch stop layer on the source/drain contact plug; and removing the second inhibitor film. In an embodiment, the second etch stop layer further comprises a portion directly over and contacting the gate stack. In an embodiment, the structure further comprises recessing the gate stack to form a recess; and forming a hard mask in the recess, wherein the first inhibitor film comprises a portion directly over and contacting the hard mask.

In an embodiment, the first etch stop layer is selectively deposited by soaking the conductive feature in a precursor. In an embodiment, the first etch stop layer is selectively deposited using a silane-containing precursor. In an embodiment, the first inhibitor film is removed through a thermal process. In an embodiment, the thermal process is performed using a precursor comprising hydrogen (H₂). In an embodiment, the first inhibitor film comprises carbon.

In accordance with some embodiments, a structure comprises a semiconductor region; a gate stack over the semiconductor region; a source/drain region aside of the gate stack; a source/drain silicide region over and contacting the source/drain region; a shallow trench isolation region aside of the source/drain region; a first contact etch stop layer on the source/drain region; and an inter-layer dielectric over the first contact etch stop layer, wherein the inter-layer dielectric is in physical contact with both of the first contact etch stop layer and the shallow trench isolation region. In an embodiment, the structure further comprises a source/drain contact plug in the inter-layer dielectric and the first contact etch stop layer, wherein the source/drain contact plug contacts the source/drain silicide region.

In an embodiment, the structure further comprises a second contact etch stop layer contacting a top surface of the source/drain contact plug; and an additional inter-layer dielectric over and contacting both of the second contact etch stop layer and the inter-layer dielectric. In an embodiment, the first contact etch stop layer comprises a first portion directly over a top surface of the source/drain region.

In an embodiment, the source/drain region comprises a downward-facing surface, and the inter-layer dielectric is in physical contact with the downward-facing surface. In an embodiment, the source/drain region comprises a downward-facing surface, and the first contact etch stop layer comprises a second portion physically contacting the downward-facing surface. In an embodiment, an entirety of the first contact etch stop layer is physically spaced apart from the shallow trench isolation region.

In accordance with some embodiments, a structure comprises a semiconductor substrate; a dielectric isolation region in the semiconductor substrate a semiconductor fin adjacent to and higher than a top surface of the dielectric isolation region; a gate stack on the semiconductor fin; a source/drain region joined to the semiconductor fin and aside of the gate stack; a source/drain silicide region on the source/drain region; a contact etch stop layer on the source/drain region and spaced apart from the dielectric isolation region; an inter-layer dielectric on and contacting the contact etch stop layer, wherein the inter-layer dielectric is further in contact with the dielectric isolation region; and a source/drain contact plug over and contacting the source/drain silicide region.

In an embodiment, the inter-layer dielectric is further in physical contact with the source/drain region. In an embodiment, the inter-layer dielectric is in physical contact with a downward-facing surface of the source/drain region, and is spaced apart from an upward-facing surface of the source/drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a gate stack over a semiconductor region;
performing an epitaxy process to form a source/drain region aside of the gate stack;
forming a source/drain contact plug over and electrically coupling to the source/drain region;
forming a gate contact plug over and electrically coupling to the gate stack;
selectively forming a first inhibitor film on a dielectric layer nearby a conductive feature, wherein the conductive feature is selected from the group consisting of the source/drain region, the source/drain contact plug, and the gate contact plug;
selectively depositing a first etch stop layer on the conductive feature, wherein the first inhibitor film prevents the first etch stop layer from being deposited thereon; and
removing the first inhibitor film.

2. The method of claim 1, wherein the conductive feature comprises the source/drain region, and wherein the first inhibitor film comprises a portion on a shallow trench isolation nearby the source/drain region.

3. The method of claim 2 further comprising:
selectively forming a second inhibitor film on a second dielectric layer nearby the source/drain contact plug;
selectively depositing a second etch stop layer on the source/drain contact plug; and
removing the second inhibitor film.

4. The method of claim 3, wherein the second etch stop layer further comprises a portion directly over and contacting the gate stack.

5. The method of claim 1 further comprising:
recessing the gate stack to form a recess; and
forming a hard mask in the recess, wherein the first inhibitor film comprises a portion directly over and contacting the hard mask.

6. The method of claim 1, wherein the first etch stop layer is selectively deposited by soaking the conductive feature in a precursor.

7. The method of claim 6, wherein the first etch stop layer is selectively deposited using a silane-containing precursor.

8. The method of claim 1, wherein the first inhibitor film is removed through a thermal process.

9. The method of claim 8, wherein the thermal process is performed using a precursor comprising hydrogen (H₂).

10. The method of claim 1, wherein the first inhibitor film comprises carbon.

11. A structure comprising:
a semiconductor region;
a gate stack over the semiconductor region;
a source/drain region aside of the gate stack;
a source/drain silicide region over and contacting the source/drain region;
a shallow trench isolation region aside of the source/drain region;
a first contact etch stop layer on the source/drain region; and
an inter-layer dielectric over the first contact etch stop layer, wherein the inter-layer dielectric is in physical contact with both of the first contact etch stop layer and the shallow trench isolation region.

12. The structure of claim 11 further comprising:
a source/drain contact plug in the inter-layer dielectric and the first contact etch stop layer, wherein the source/drain contact plug contacts the source/drain silicide region.

13. The structure of claim 12 further comprising:
a second contact etch stop layer contacting a top surface of the source/drain contact plug; and
an additional inter-layer dielectric over and contacting both of the second contact etch stop layer and the inter-layer dielectric.

14. The structure of claim 11, wherein the first contact etch stop layer comprises a first portion directly over a top surface of the source/drain region.

15. The structure of claim 14, wherein the source/drain region comprises a downward-facing surface, and the inter-layer dielectric is in physical contact with the downward-facing surface.

16. The structure of claim 14, wherein the source/drain region comprises a downward-facing surface, and the first contact etch stop layer comprises a second portion physically contacting the downward-facing surface.

17. The structure of claim 11, wherein an entirety of the first contact etch stop layer is physically spaced apart from the shallow trench isolation region.

18. A structure comprising:
a semiconductor substrate;
a dielectric isolation region in the semiconductor substrate
a semiconductor fin adjacent to and higher than a top surface of the dielectric isolation region;
a gate stack on the semiconductor fin;
a source/drain region joined to the semiconductor fin and aside of the gate stack;
a source/drain silicide region on the source/drain region;
a contact etch stop layer on the source/drain region and spaced apart from the dielectric isolation region;
an inter-layer dielectric on and contacting the contact etch stop layer, wherein the inter-layer dielectric is further in contact with the dielectric isolation region; and
a source/drain contact plug over and contacting the source/drain silicide region.

19. The structure of claim 18, wherein the inter-layer dielectric is further in physical contact with the source/drain region.

20. The structure of claim 18, wherein the inter-layer dielectric is in physical contact with a downward-facing surface of the source/drain region, and is spaced apart from an upward-facing surface of the source/drain region.
